(19) United States
(12) Patent Application Publication
(10) Pub. No.: US 2009/0180261 A1
(43) Pub. Date: Jul. 16, 2009

(54) FAULT CIRCUIT INTERRUPTER DISPOSED INSIDE A HOUSING ADAPTED TO RECEIVE MODULAR COMPONENTS

(75) Inventors: Mario ANGELIDES, Rockville Centre, NY (US); Michael KAMOR, North Massapequa, NY (US)

Correspondence Address: Collard & Roe, P.C./Leviton, 1077 Northern Blvd, Roslyn, NY, 11576, US

(73) Assignee: LEVITON MANUFACTURING COMPANY, INC., Little Neck, NY (US)

(21) Appl. No.: 12/014,347

(22) Filed: Jan. 15, 2008

(51) Int. Cl. H05K 7/00

(52) U.S. Cl. 361/747; 361/728

(57) ABSTRACT

A modular electronic device comprising a housing and at least one phase conductor, and at least one neutral conductor coupled to the housing. The housing has at least one receptacle for receiving a modular component when this modular component is inserted therein. The housing has at least one module release button coupled to the housing wherein when said module release button is pressed, the modular component is released from the housing. In at least one embodiment, the modular component is an electrical component, wherein the electrical component is electrically coupled to the at least one phase conductor and the at least one neutral conductor when the module is inserted into the housing. In at least one embodiment, the modular component has a power blade which connects the modular electrical component to the conductors of the housing. In at least one of these embodiments, the power blade is formed as a key which has at least one prong which uniquely identifies said modular component. In this way, the housing is adapted to have a complementary structure which accepts only modular components having this form of power blade.

### BACKGROUND

The invention relates to fault circuit interrupter which is disposed inside a housing adapted to receive modular components. Once these modular components are received inside of this housing and electrically connected to a circuit inside the housing, they are then electrically coupled to this fault circuit interrupter.

### SUMMARY

The invention relates to a modular electronic device comprising a housing at least one phase conductor, and at least one neutral conductor coupled to the housing. The housing has at least one receptacle for receiving a modular component when this modular component is inserted therein. The housing has at least one module release button coupled to the housing wherein when the module release button is pressed, the modular component is released from the housing. In at least one embodiment, the modular component is an electrical component, wherein the electrical component is electrically coupled to the at least one phase conductor and the at least one neutral conductor when the module-component is inserted into the housing.

In at least one embodiment, the modular component has a power blade which connects the modular electrical component to the conductors of the housing. In at least one of these embodiments, the power blade is formed as a key which has at least one prong which uniquely identifies the modular component. In this way, the housing is adapted to have a complementary structure which accepts only modular components having this form of power blade.

In at least one embodiment, when the module is placed inside of the housing it is coupled to the fault circuit interrupter such that power to each module is controlled by the fault circuit interrupter.

### BRIEF DESCRIPTION OF THE DRAWINGS

Other objects and features of the present invention will become apparent from the following detailed description considered in connection with the accompanying drawings. It is to be understood, however, that the drawings are designed as an illustration only and not as a definition of the limits of the invention.

In the drawings, wherein similar reference characters denote similar elements throughout the several views:

FIG. 1 is a perspective view of a first embodiment of the invention;

FIG. 2 is a perspective view of the embodiment shown in FIG. 1 wherein the module is ejected from the housing;

FIG. 3 is a front view of another embodiment of the invention;

FIG. 4 is a front view of another embodiment of the invention;

FIG. 5 is a front perspective view of an embodiment of a modular component;

FIG. 6 is a back perspective view of an embodiment of a modular component;

FIG. 7 is a top, cross-sectional view of a first embodiment of a modular component;

FIG. 8 is a side cross-sectional view of a second embodiment of a modular component; and

FIG. 9A is a cross-sectional view of an embodiment of a housing; and

FIG. 9B is a cross-sectional view of a receptacle;

FIG. 9C is a back view of another embodiment of an opening in a housing;

FIG. 10 is a top, cross sectional view of the device which shows a front cover disposed in front of an eject button.

### DETAILED DESCRIPTION

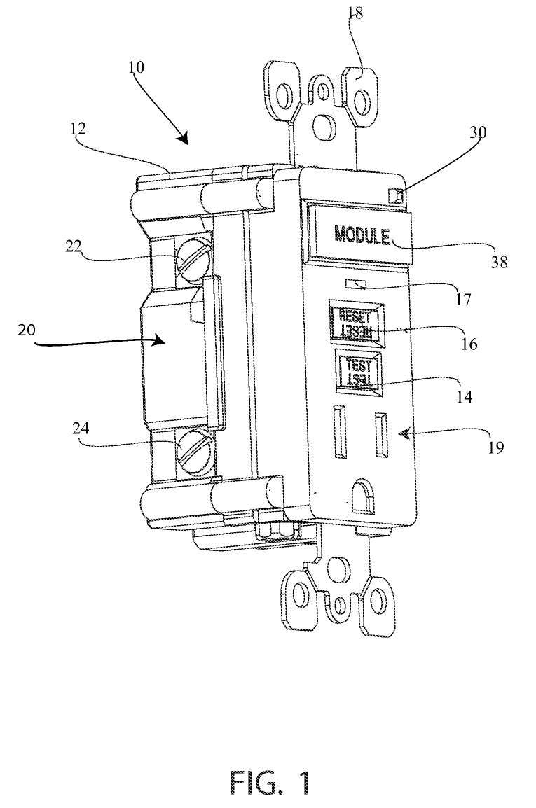

Referring to the drawings, FIG. 1 is a perspective view of a first embodiment of the invention. In this embodiment 10, there is a housing 12 for an electronic component which is formed as a GFCI or ground fault circuit interrupter, having a test button 14, and a reset button 16, a LED indicator light 17, a strap 18, a receptacle interface 19, and electrical contacts 20. Test button 14 and reset button 16 are known in the art and are described in greater detail in U.S. Pat. No. 4,595,894 to Doyle et al issued on Jun. 17, 1986 the disclosure of which is hereby incorporated herein by reference in its entirety. Alternatively, however, the housing and the modular components can be used in a non-GFCI or non fault circuit type device.

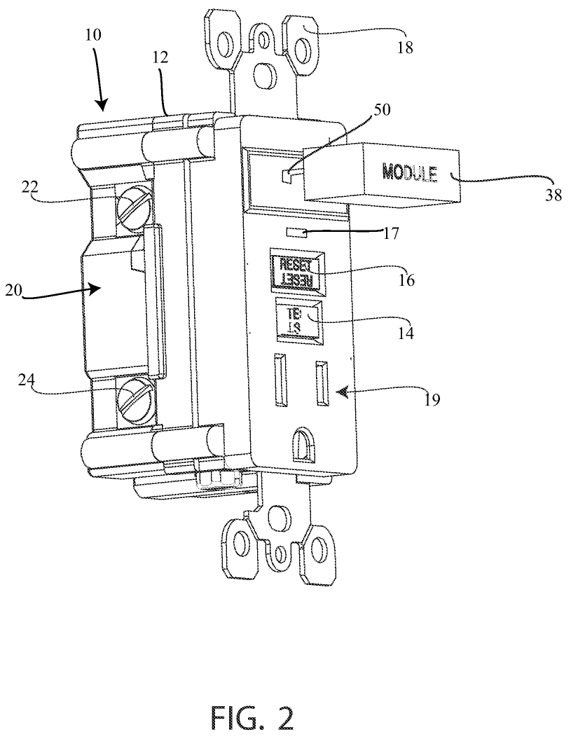

Electrical contacts 20 include line neutral contacts 22 which are formed as conductors and load neutral contacts 24 which are formed as conductors, as well as line phase contacts (not shown) and load phase contacts (not shown). On the front face of housing 12, is a module release button or element 30. When a module release button is pressed, it is designed to release a module 38 from housing 12 (See FIG. 2). It should be noted that the module release button may be placed anywhere on the device as considerations may require. This button may alternately be located in a place that is inaccessible to the user once installed. Alternatively, the button may be accessible to the user once installed but only with the removal of a wallplate.

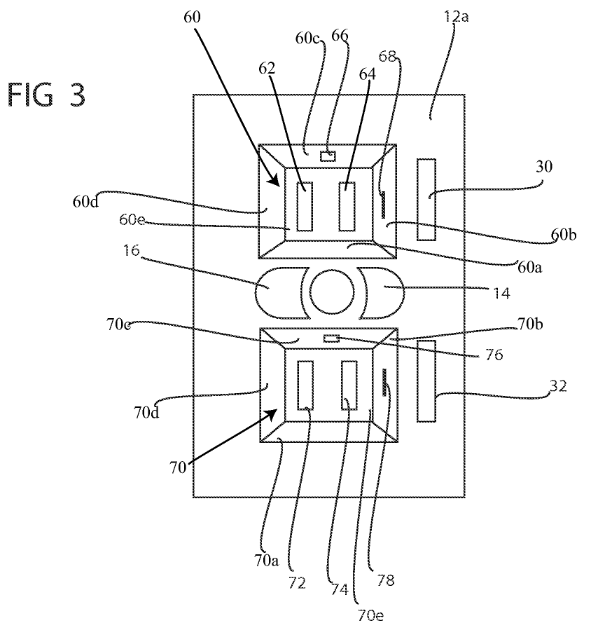

FIG. 2 is a perspective view of the embodiment shown in FIG. 1 wherein the module is ejected from the housing. In this view, module 38 has at least one power blade 50, wherein when the modular component is inserted into housing 12, the power blade is coupled to at least one of the phase conductors or neutral conductors (See FIG. 3).

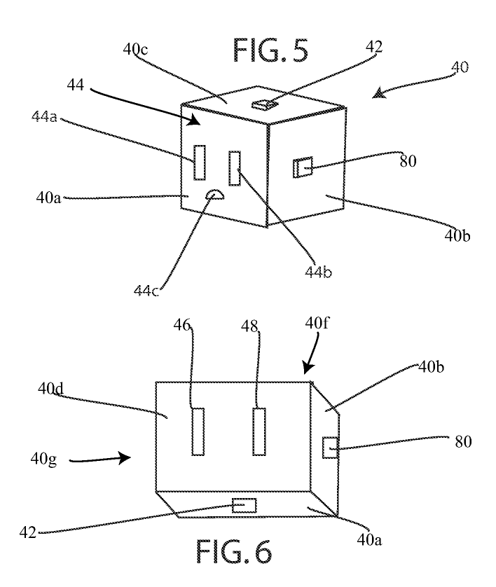

FIG. 3 is a front view of another embodiment of the invention wherein in this embodiment there is shown a housing 12a which has at least two receptacles 60 and 70. These receptacles can be in any known shape but are shown here as substantially rectangular shaped. Receptacle 60 has five sides or faces, including a first face 60a, a second face 60b, a third face 60c, a fourth face 60d, and a fifth face 60e. First face 60a has no electrical contacts, second face 60b does not contain electrical contacts but it does contain a notch or opening 68 which is designed to receive a lock or latch (see FIGS. 5,6 and 7). Third face 60c includes a contact 66 which is a ground contact for coupling to an associated ground contact 42 (see FIG. 5) on an associated module. Face 60d also does not contain electrical contacts, however face 60e which is the back face of this receptacle has two contacts or conductors, a neutral contact 62 in the form of a conductor and a phase contact 64 in the form of a conductor. When a module is inserted into receptacle 60, it is electrically connected to these contacts.

Receptacle 70 has five sides or faces, including a first face 70a, a second face 70b, a third face 70c, a fourth face 70d, and a fifth face 70e. First face 70a has no electrical contacts, second face 70b does not contain electrical contacts but it does contain a notch or opening 78 which is designed to receive a lock or latch (see FIGS. 5,6 and 7). Third face 70c includes a contact 76 which is a ground contact for coupling to an associated ground contact 42 (see FIG. 5) on an associated module. Face 70d also does not contain electrical contacts, however face 70e which is the back face of this receptacle has two contacts, a neutral contact 72 and a phase contact 74. When an associated module 40 is inserted into receptacle 70, it is electrically connected to these contacts.

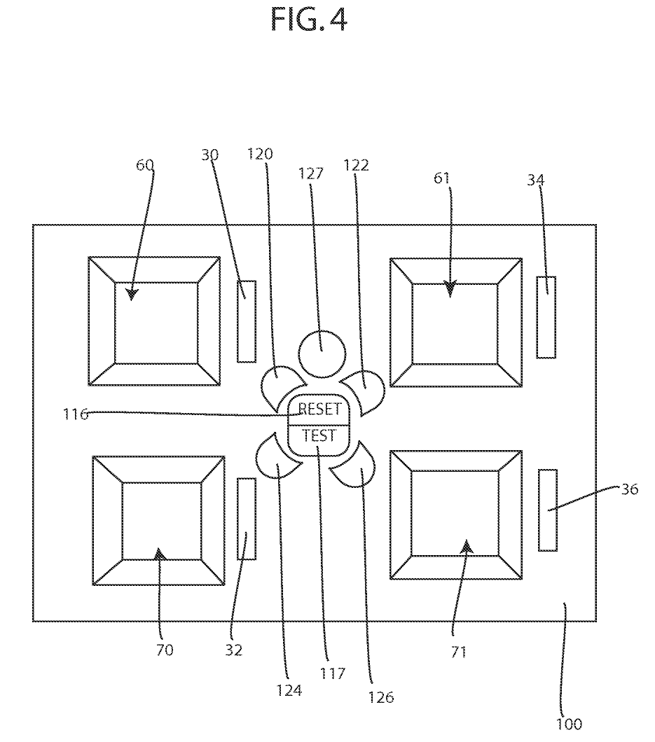

FIG. 4 is a front view of another embodiment of the invention which shows a front view of a double gang modular housing 100 which has four receptacles 60, 61, 70, and 71 for receiving associated modules. These receptacles are the same as the receptacles that were explained in greater detail in FIG. 3. Housing 100 includes a plurality of eject buttons 30, 32, 34, and 36 disposed adjacent to housings 60, 70, 61, and 71 respectively. In addition, this housing also has a reset button 116 and a test button 117. A series of associated LED lights are disposed around reset button 116 and test button 117 including LED indicator lights 120, 122, 124, 126 and 127. LED indicator lights 120, 122, 124 and 126 are designed to indicate whether the associated module has been inserted into associated housings 60, 61, 70 and 71. LED light 127 is a GFCI indicator light which indicates whether the GFCI is in a set or tripped state.

FIG. 5 is a front perspective view of an embodiment of a modular component. In this case, modular component 40 can be of any shape but in this embodiment is formed as a block which has six sides. This block has a cross section that is substantially in the form of a rectangle.

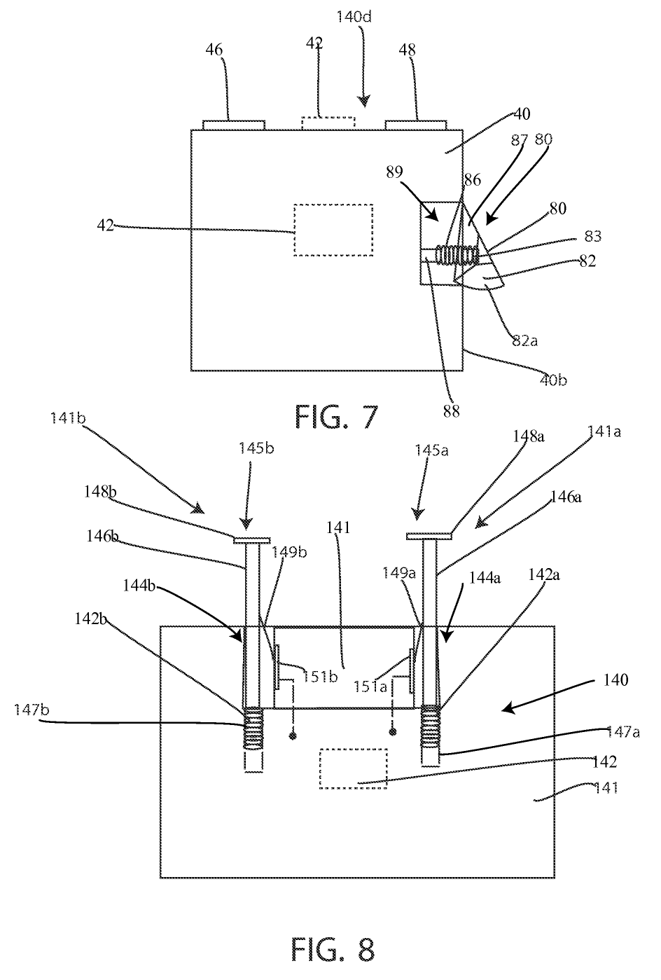

Modular component 40 includes a housing front face 40a which has, in this view, a functional component 44 which as shown in this embodiment are receptacle openings 44a, 44b and 44c comprising phase, neutral and ground openings respectively. A second face 40b includes a locking element 80 which is in the form of a spring loaded locking element (See FIG. 7). In this case, locking element 80 has a hinge which in this embodiment is formed as a natural hinge. Face 40c which is shown as a top face has a ground contact 42.

FIG. 6 is a back perspective view of the embodiment of the modular component shown in FIG. 5. For example, with this design, there is shown a back face 40d which has phase and neutral contacts 46 and 48, respectively which are formed as metal contacts formed in the housing, wherein modular component 40 can be inserted into an associated receptacle such as any one of receptacles 60, 61, 70, or 71 and be electrically connected to contacts in the housing such as contacts 62, 64, 72, and 74. In this case, for example, when module 40 is inserted into receptacle 60, phase contact 46 contacts the associated phase contact 64, neutral contact 48 contacts the associated neutral contact 62 to form an electrical connection. In addition ground contact 42 contacts associated ground contact 66 to form a ground contact connection.

FIG. 7 is a top, cross-sectional view of a first embodiment of a modular component 40 which shows locking element 80 which has a hinge in the form of a natural hinge 81, a body section 82, a spring 86 and a support shaft 88 coupled to body section 82 of locking element 80. Spring 86 is formed so that it is stabilized on locking shaft 88, but disposed inside of a housing section 89. In this case, support shaft 83 locks the spring 86 as well opposite locking shaft 88. This body section also has a recessed region 87 for storing a section of spring 86. When modular element 40 is pressed into an associated receptacle, body section 82 is pressed into housing section 89 to collapse this locking element into the modular element. In this state, spring 86 is thereby compressed and body section 82 is pressed flush against wall 40b of modular component 40. When this modular component is fully inserted into the receptacle, spring 86 presses locking body section 82 out thereby expanding into opening 89.

FIG. 8 shows a top cross-sectional view of another embodiment of a modular component 140 which can also be used to represent the inner workings of modular component 38. In this case, the modular component 140 includes a ground contact 142, and a plurality of spring loaded contacts 145a and 145b in the form of a phase contact 145a and a neutral contact 145b. Phase contact 145a and neutral contact 145b are each formed as a plunger or power blade which provides power to the functional part of the modular component. Contacts 145a and 145b include springs 142a, and 142b which are coupled to shafts 146a and 146b. These spring loaded contacts or plunger 145a and 145b are disposed inside housings 144a and 144b. Shafts 146a and 146b are made from a conductive material such as metal and extend inside of housing 141a and 141b and are coupled to associated face terminals, or to an integrated electronic component in housing 141. For example, shafts 146a and 146b are housed inside of associated contact shafts 147a and 147b which are in communication with electrical components disposed inside of housing 141.

For example, there are brush contacts 149a and 149b which are coupled to shafts 146a and 146b respectively and are in contact with plate contacts 151a and 151b respectively. Essentially, these spring loaded contacts 145a and 145b are compressible so that modular component 140 can be inserted inside of the associated receptacle 60 inside of housing 12. These power blades 145a and 145b can have respective associated key sections 145a or 145b which mate with a corresponding opening.

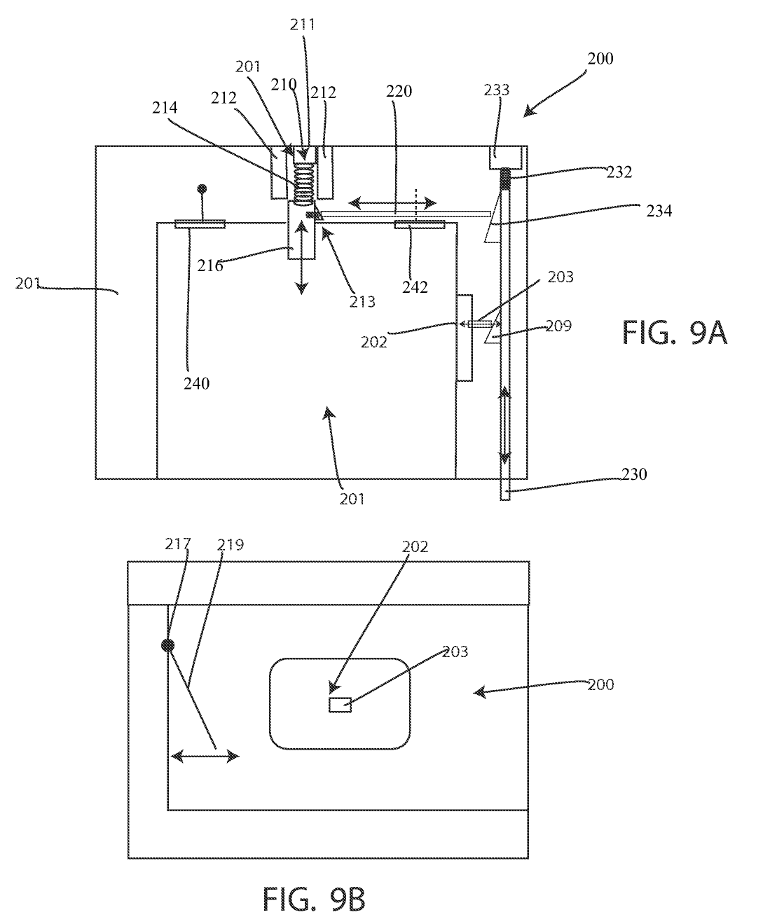

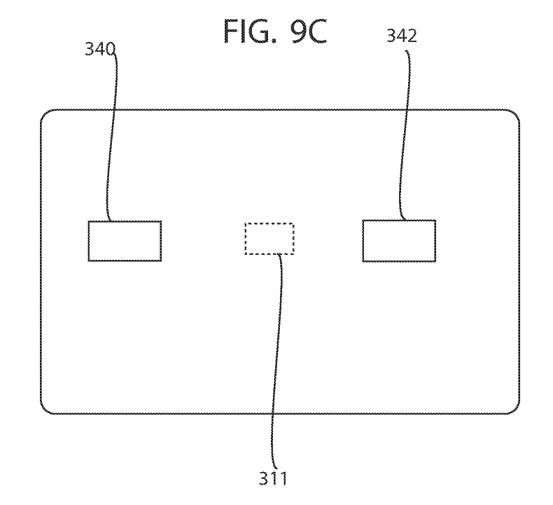

FIG. 9A is a top view of an alternative embodiment of housing 200 showing an ejection or release mechanism for ejecting a modular component such as modular component 40 from a housing or receptacle 60 or 200. For example, in this embodiment, there is a receptacle or housing 200 which has a receptacle region 201 which includes a release or ejection device or mechanism 210. Release or ejection device or mechanism 210 includes a base 211 which is coupled to a spring 214. Spring 214 is substantially disposed inside of housing 212 which is used to guide spring 214 and a plunger 216. Plunger 216 has a locking element or mechanism 213 coupled to it, and which is formed similar to a snap lock such as snap lock 80. This snap lock 213 selectively locks plunger 216 in place.

Housing 200 has an opening wherein this opening is adapted to receive an actuator arm 220 which is essentially part of the release mechanism which moves axially along a shaft region formed in housing 200. Actuator arm 220 is acted on by pressing arm 230 which has a ramp section 234 which is used to drive actuator arm 220 in an axial manner as an axial to axial translation Pressing arm or plunger 230 forms at a first end an eject button such as eject button 30 shown in FIG. 2. At the opposite end of pressing arm 230 is a spring 232 which is coupled to a base 233. When a user presses on pressing arm 230 it drives ramp 234 against actuator arm 220 causing an axial movement of actuator arm 220 against snap lock 213, thereby releasing plunger 216 causing spring 214 to drive plunger 216 causing plunger 216 to release and press against an associated module 40, driving module 40 outside of housing 201.

In addition, inside of housing 200 are contacts in the form of electrical contacts 240 and 242. For example, contact 240 is a neutral electrical contact which is in contact with an associated neutral line, while contact 242 is a phase contact in contact with an associated phase line.

Thus, when any one of the modules including modules 38, 40 and 140 are inserted into receptacle 201, the contacts such as blade 50 or module 38, contacts 46 and 48 on module 40, or key contacts 148a and 148b on module 140 contact these contacts to form an electrical connection with an electrical device inside of either module 40 or module 140. Thus, with this design, each of the modules is protected or controlled by an associated fault circuit such as a GFCI. Thus, even if the design is associated with a double gang enclosure, a single fault circuit can control four modules in the associated housing.

FIG. 9C shows another embodiment of a receptacle such as receptacle 60, which has openings 340, or 342 which are adapted to receive associated keys 148a or 148b, wherein these keys are used to lock the modular component into the housing. In addition, there is a plunger or eject shaft 311 similar to plunger 216 which is used to eject a modular component from a housing. The substantially rectangular shapes of openings 340 and 342 are shown to represent unique openings which are adapted to receive associated keys.

In all, multiple different kinds of functional elements can be disposed inside of these modules. Some of these functional elements include: outlets, switches, timers, occupancy sensors, clocks, dimmers, tamper resistant switches, nightlights, air fresheners, blanks for unused ports, radios and carbon monoxide detectors. Other types of electronic functional components can be used as well.

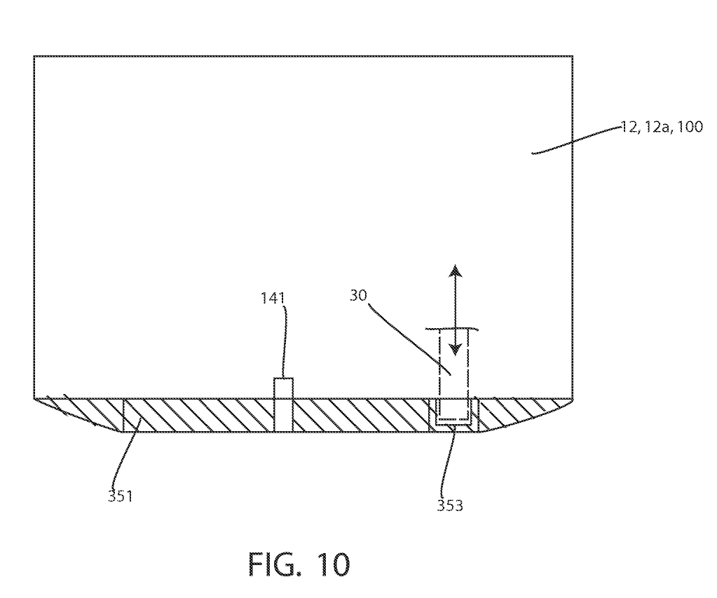

FIG. 10 shows an additional version which has a front cover 351 which is coupled to a front face of housing 12, 12a or 100 which is designed to cover over the eject button 30, or 230 in a covering region 353 when cover 351 is coupled to housing 12, 12a or 100. Thus, with this design, once the modules are inserted into their respective receptacles, the eject button is covered over to protect these modules from being unnecessarily ejected. In addition in this embodiment, the cover 351 can be coupled to housing 12, 12a, or 100 in any manner. With this view, the cover is coupled to the associated housing via a screw which in this embodiment is in the form of a counter sunk screw. In this embodiment the counter sunk screw is a tamper resistant screw, however other alternative means for coupling the cover to the housing can be used as well.

Accordingly, while only a few embodiments of the present invention have been shown and described, it is obvious that many changes and modifications may be made thereunto without departing from the spirit and scope of the invention.

What is claimed is:

1. A modular electronic device comprising:
a) a housing;
b) at least one phase conductor coupled to said housing;
c) at least one neutral conductor coupled to said housing;
d) at least one modular component insertable into said housing; and
e) at least one fault circuit interrupter disposed in said housing and in communication with said at least one phase conductor and said at least one neutral conductor to selectively switch whether said at least one phase conductor and said at least one neutral conductor receive power, wherein when said at least one modular component is inserted into said housing, said at least one modular component is electrically coupled to said at least one phase conductor and said at least one neutral conductor.

2. The modular electronic device as in claim 1, wherein said housing is a single gang electrical enclosure having at least one receptacle, wherein said at least one modular component is insertable into said at least one receptacle.

3. The modular electronic device as in claim 1, wherein said at least one modular component is formed as a self contained unit which has a substantially rectangular cross-section. and which further comprises at least one phase contact and at least one neutral contact.

4. The modular electronic device as in claim 1, further comprising at least one module release button coupled to said housing wherein when said at least one module release button is pressed, said at least one modular component is released from said housing.

5. The modular electronic device as in claim 4, wherein said at least one modular component further comprises a plurality of faces, with a first face including said at least one phase contact and said at least one neutral contact.

6. The modular electronic device as in claim 5, wherein said at least one phase contact and said at least one neutral contact are disposed on said first face and wherein said at least one modular component further comprises a ground contact disposed on a different face as said at least one phase contact and said at least one neutral contact.

7. The modular electronic device as in claim 1, wherein said at least one modular component further comprises a housing, at least one spring coupled to said housing and at least one locking button coupled to said spring and to said housing, wherein said at least one locking button is spring loaded inside of said modular component housing.

8. The modular electronic device as in claim 1, wherein said housing has at least one test button and at least one reset button.

9. The modular electronic device as in claim 8, wherein said housing further comprises at least two LED lights for indicating whether an electrical component is electrically coupled to said at least one fault circuit interrupter.

10. The modular electronic device as in claim 1, wherein said at least one modular component has at least one release element which releases the modular component from the housing when said at least one module release button is pressed.

11. The modular electronic device as in claim 10, wherein said modular component has a body section and said at least one release element further comprises at least one plunger and at least one spring, wherein said at least one spring is coupled to said at least one plunger and said spring is also coupled to said body section wherein when said at least one modular component is inserted into said housing said at least one plunger inserts into said modular component body section.

12. The modular electronic device as in claim 1, wherein said housing has at least one release element for ejecting said at least one modular component from said housing.

13. The modular electronic device as in claim 12, wherein said at least one release element further comprises at least one spring and at least one plunger, said at least one spring being coupled to said at least plunger at a first end and to said housing at a second end.

14. The modular electronic device as in claim 13, further comprising a cover which is connectable to said housing and which is adapted to cover said at least one release element to prevent actuation of said at least one release element.

15. The modular electronic device as in claim 1, wherein said at least one modular component further comprises at least one power blade which is coupled to said at least one modular component, wherein said at least one power blade is shaped to fit inside said housing.

16. The modular electronic device as in claim 15, wherein said at least one power blade is shaped as a key, and wherein said housing has a hole that is adapted in a complementary manner to receive said key.

17. The modular electronic device as in claim 1, wherein said housing comprises a double gang electrical enclosure.

18. The modular electronic device as in claim 1, wherein said modular component comprises at least one modular component selected from the group consisting of: an outlet, a switch a timer, an occupancy sensor, a clock, a dimmer, a tamper resistant switch, a nightlight, an air freshener, a blank, a radio, and a carbon monoxide detector.

19. A modular electronic device comprising:
a) a housing in the form of a double gang electrical enclosure having at least two receptacle enclosures with each receptacle enclosure comprising:
i) at least one phase conductor coupled to said housing
ii) at least one neutral conductor coupled to said housing;
b) at least one modular component insertable into said housing;
c) at least one module release button coupled to said housing wherein when said at least one module release button is pressed, said at least one modular component is released from said housing.

20. The modular electronic device as in claim 19, wherein said modular component comprises at least one modular component selected from the group consisting of: an outlet, a switch a timer, an occupancy sensor, a clock, a dimmer, a tamper resistant switch, a nightlight, an air freshener, a blank, a radio, and a carbon monoxide detector.

21. The modular electronic device as in claim 19, wherein said modular component further comprises at least one power blade, wherein when said modular component is inserted into said housing, said at least one power blade is coupled to at least one of said at least one phase conductor or said at least one neutral conductor and wherein said at least one power blade is in the form of a key having at least one prong for selectively identifying said modular component.

22. The modular electronic device as in claim 19, wherein said housing further comprises a plurality of LED components wherein each of said plurality of LED components comprises at least two different LED lights with a first light indicating an electrical connection between said modular component and said housing and said second light indicating the fault status of the electronic device.

23. The modular electronic device as in claim 19, wherein said modular electronic device is a fault circuit device, and wherein said housing further comprises at least one fault circuit, which has a switch, and wherein said housing is adapted to receive at least four modular components, wherein said fault circuit has a switch which controls whether power flows to each of said at least four modular components, and wherein said housing further comprises at least one test button and at least one reset button.

24. A modular component for insertion into a housing comprising:
a) a body section;
b) at least one power blade forming a conductor extending from said body section;
c) at least one key coupled to said at least one power blade, said at least one key for insertion into a complementary opening in the housing, said at least one key being adapted to fit into the complementary opening in the housing.
